(19) United States
(12) Patent Application Publication
(10) Pub. No.: US 2025/0364014 A1
(43) Pub. Date: Nov. 27, 2025

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: Kang Lib KIM, SUWON-SI (KR); Dongjin LEE, SUWON-SI (KR); Jaeduk LEE, SUWON-SI (KR)

(21) Appl. No.: 18/954,739

(22) Filed: Nov. 21, 2024

(30) Foreign Application Priority Data
May 22, 2024 (KR) 10-2024-0066478

(51) Int. Cl. G11C 5/06; H01L 25/065; H10B 41/10; H10B 41/35; H10B 43/10; H10B 43/35; H10B 80/00

(52) U.S. Cl. CPC G11C 5/063; H01L 25/0652; H10B 41/10; H10B 41/35; H10B 43/10; H10B 43/35; H10B 80/00; H01L 2225/06506

(57) ABSTRACT

A semiconductor device includes a substrate, a first mold structure including a plurality of first insulating layers and a plurality of first gate layers which are alternately stacked on the substrate, a second mold structure disposed on the first mold structure, including a plurality of second insulating layers and a plurality of second gate layers which are alternately stacked, a plurality of first word line contacts extending through the first mold structure and each being connected to one of the plurality of first gate layers, a plurality of second word line contacts extending through the second mold structure and each being connected to one of the plurality of second gate layers, and a plurality of first through vias extending through the second mold structure and electrically connected to the plurality of first word line contacts.

### CROSS-REFERENCE TO RELATED APPLICATION

This patent application claims priority under 35 U.S.C. § 119 to Korean Patent Application No. 10-2024-0066478, filed in the Korean Intellectual Property Office on May 22, 2024, the disclosure of which is incorporated by reference in its entirety herein.

### 1. Technical Field

The present disclosure is directed to a semiconductor device and an electronic system including the same.

### 2. Discussion of Related Art

There is great demand for semiconductor devices capable of storing high-capacity data in electronic devices that require data storage. Semiconductor memory is a semiconductor device used to store data and program code in digital systems such as computers and smartphones. Semiconductor memory originally included a two-dimensional arrangement of memory cells, where memory cells are laid out horizontally across a single layer of semiconductor wafer. As a result, the storage capacity is limited by the physical surface area of the chip. Semiconductor memory was then developed including a three-dimensional arrangement of memory cells to increase storage capacity. For example, multiple layers of memory cells are stacked vertically on top of one another in this three-dimensional arrangement.

The capacity and integration of a semiconductor memory may be increased by reducing the minimum separation distance between some components. However, in a high-capacity and highly integrated semiconductor memory, it may be difficult to reduce the minimum separation distance without introducing defects during a manufacturing process. Accordingly, a new method is needed to reduce the minimum separation distance between components, enabling further integration of semiconductor devices.

### SUMMARY

A semiconductor device according to an embodiment includes a substrate, a first mold structure, a second mold structure, a plurality of first word line contacts, a plurality of second word line contacts and a plurality of first through vias. The first mold structure includes a plurality of first insulating layers and a plurality of first gate layers which are alternately stacked on the substrate. The second mold structure is disposed on the first mold structure and includes a plurality of second insulating layers and a plurality of second gate layers which are alternately stacked. The plurality of first word line contacts extend through the first mold structure and each is connected to a corresponding one of the plurality of first gate layers. The plurality of second word line contacts extend through the second mold structure and each is connected to a corresponding one of the plurality of second gate layers. The plurality of first through vias extend through the second mold structure and are electrically connected to the plurality of first word line contacts.

A semiconductor device according to an embodiment includes a substrate, a lower mold structure, an upper mold structure, a plurality of lower word line contacts, a plurality of upper word line contacts and a plurality of through vias. The lower mold structure includes a plurality of lower insulating layers and a plurality of lower gate layers which are alternately stacked on the substrate. The upper mold structure is disposed on the lower mold structure, and includes a plurality of upper insulating layers and a plurality of upper gate layers which are alternately stacked. The plurality of lower word line contacts are disposed at equal intervals along a predetermined direction in the lower mold structure and are each connected to a corresponding one of the plurality of lower gate layers. The plurality of upper word line contacts are disposed at equal intervals along the predetermined direction in the upper mold structure and are each connected to a corresponding one of the plurality of upper gate layers. The plurality of through vias are disposed at equal intervals along the predetermined direction in the upper mold structure, corresponding to the plurality of lower word line contacts in a plan view, and electrically connected to the plurality of lower word line contacts.

An electronic system according to an embodiment includes a main substrate, a semiconductor device on the main substrate, and a controller electrically connected to the semiconductor device on the main substrate. The semiconductor device includes a substrate, a first mold structure, a second mold structure, a plurality of first word line contacts, a plurality of second word line contacts and a plurality of first through vias. The first mold structure includes a plurality of first insulating layers and a plurality of first gate layers which are alternately stacked on the substrate. The second mold structure is disposed on the first mold structure and includes a plurality of second insulating layers and a plurality of second gate layers which are alternately stacked. The plurality of first word line contacts extend through the first mold structure and each is connected to a corresponding one of the plurality of first gate layers. The plurality of second word line contacts extend through the second mold structure and are each connected to a corresponding one of the plurality of second gate layers. The plurality of first through vias extend through the second mold structure and are electrically connected to the plurality of first word line contacts.

According to some embodiments of the present disclosure, the separation distance between adjacent word line contacts can be reduced to be less than the separation distance between adjacent word line contacts in the absence of the through via. Through this, the degree of integration of the semiconductor device can be increased.

According to some embodiments of the present disclosure, the lowermost via spacer of a plurality of via spacers can cover a region spanning from at least the through via to the upper edge of the first word line contact in the outward direction. Through this, short circuits may be prevented from occurring between the gate layer positioned at the same level as the lowermost via spacer and the first word line contact, thereby increasing contact reliability in an extension region of the semiconductor device.

### BRIEF DESCRIPTION OF THE DRAWINGS

FIG. 1 is a circuit diagram conceptually illustrating a memory array region of a semiconductor device according to an embodiment;

FIG. 2 is an example layout diagram illustrating a semiconductor device according to an embodiment;

FIG. 3 is a cross-sectional view taken along line A-A of FIG. 2 according to an embodiment;

FIG. 4 is a cross-sectional view of the semiconductor device according to an embodiment;

FIG. 5 is a cross-sectional view taken along line A-A of FIG. 4 according to an embodiment;

FIG. 6 is a cross-sectional view taken along line B-B of FIG. 4 according to an embodiment;

FIG. 7 is a diagram illustrating in detail structures of the first word line contact and the through via of FIG. 4 according to an embodiment;

FIG. 8 is a diagram illustrating another example of the through via of FIG. 7 according to an embodiment;

FIG. 9 is a view illustrating a modified example of the spacers of FIG. 7 according to an embodiment;

FIG. 10 is a diagram illustrating the second word line contact of FIG. 4 in detail according to an embodiment;

FIG. 11 is a cross-sectional view of the semiconductor device further including a third mold structure according to an embodiment;

FIGS. 12A and 12B are cross-sectional views taken along line A-A of FIG. 11 according to an embodiment;

FIG. 13 is a diagram illustrating a method for manufacturing a semiconductor device according to an embodiment;

FIG. 14 is a diagram illustrating a method for manufacturing a semiconductor device according to an embodiment;

FIG. 15 is a diagram illustrating a method for manufacturing a semiconductor device according to an embodiment;

FIG. 16 is a cross-sectional view illustrating a semiconductor device according to an embodiment;

FIG. 17 is a diagram schematically illustrating an electronic system including a semiconductor device according to an embodiment;

FIG. 18 is a perspective view schematically illustrating an electronic system including a semiconductor device according to an embodiment;

FIG. 19 is a cross-sectional view schematically illustrating a semiconductor package according to an embodiment.

### DETAILED DESCRIPTION

The singular forms “a,” “an,” and “the” as used herein are intended to include the plural forms as well, unless the context clearly indicates the singular forms. Further, the plural forms are intended to include the singular forms as well, unless the context clearly indicates the plural forms.

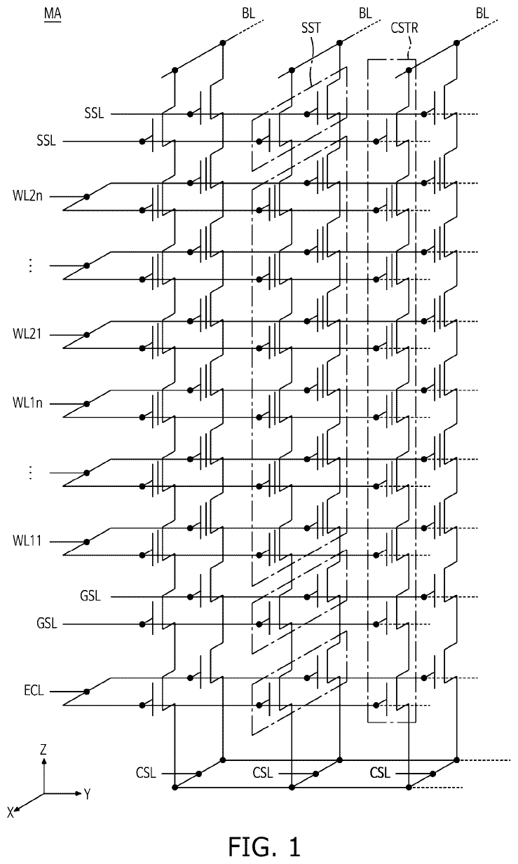

Hereinafter, various embodiments of the present disclosure will be described with reference to FIGS. 1 to 19. The same reference numerals may refer to the same components throughout the description.

FIG. 1 is a circuit diagram conceptually illustrating a memory array region MA of a semiconductor device.

A memory array of the semiconductor device may include a common source line CSL, a plurality of bit lines BL, a plurality of cell strings CSTR disposed between the common source line CSL and the plurality of bit lines BL. The common source line CSL may provide a common ground or reference potential and help in stabilizing the source voltage of memory cells of the memory array. The bit lines BL are conductive lines responsible for carrying data to and from the memory cells. The cell strings CSTR are chains of memory cells connected in series between the bit lines BL and the common source line CSL.

The common source line CSL may extend in a first direction X. In some embodiments, the plurality of common source lines CSL may be arranged two-dimensionally. For example, the plurality of common source lines CSL may be spaced apart from each other and may extend in the first direction X, respectively. The same voltage may be applied to the common source lines CSL, or different voltages may be applied for separate controlling.

The plurality of bit lines BL may be arranged two-dimensionally. For example, the plurality of bit lines BL may be spaced apart from each other and may extend in a second direction Y intersecting the first direction X, respectively. The plurality of cell strings CSTR may be connected to each of the bit lines BL in parallel. The cell strings CSTR may be coupled to the common source line CSL in common. That is, the plurality of cell strings CSTR may be disposed between the bit lines BL and the common source line CSL.

Each of the cell strings CSTR may include a ground select transistor connected to the common source line CSL, a string select transistor connected to the bit line BL, and a plurality of memory cell transistors disposed between the ground select transistor and the string select transistor. Each of the memory cell transistors may include a data storage element. The ground select transistor, the string select transistor, and the memory cell transistors may be connected to each other in series.

The common source line CSL may be connected to sources of the ground select transistors in common. In addition, a ground select line GSL, a plurality of word lines WL11 to WLIn and WL21 to WL2n, and a string select line SSL may be disposed between the common source line CSL and the bit line BL. The ground select line GSL may be used as a gate electrode of the ground select transistor, the word lines WL11 to WLIn and WL21 to WL2n may be used as a gate electrode of the memory cell transistors, and the string select line SSL may be used as a gate electrode of the string select transistor.

In some embodiments, an erase control transistor may be disposed between the common source line CSL and the ground select transistor. The common source line CSL may be connected to sources of the erase control transistors in common. In addition, an erase control line ECL may be disposed between the common source line CSL and the ground select line GSL. The erase control line ECL may be used as a gate electrode of the erase control transistor. The erase control transistors may generate a gate-induced drain leakage (GIDL) to perform an erase operation of the memory cell array.

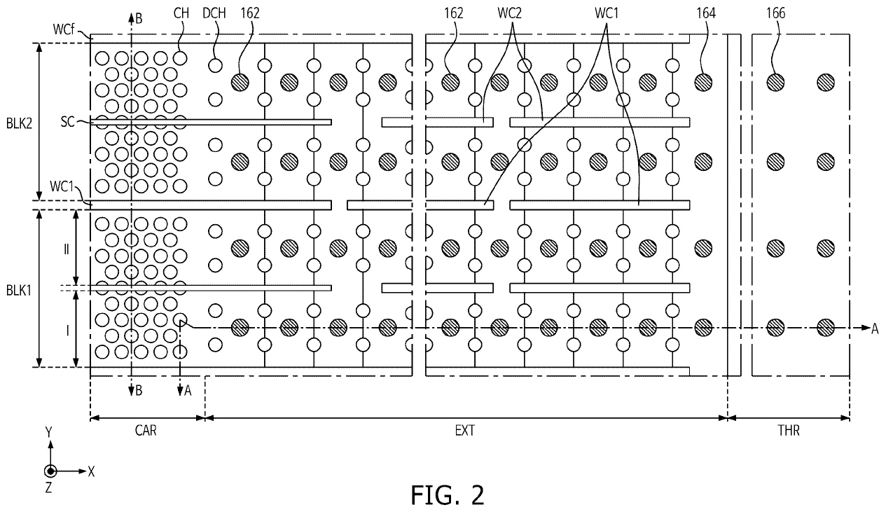

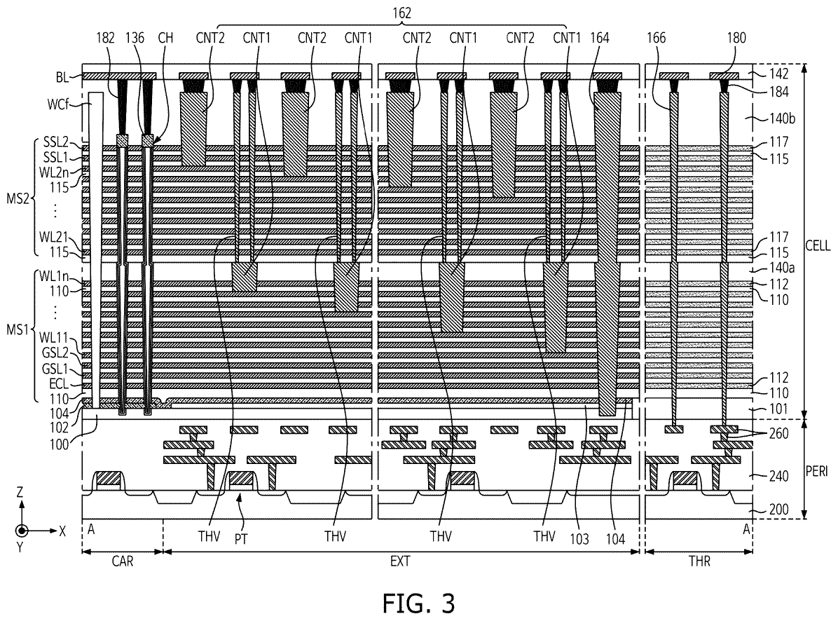

FIG. 2 is an example layout diagram illustrating a semiconductor device. FIG. 3 is a cross-sectional view taken along line A-A of FIG. 2.

Referring to FIGS. 2 and 3, the semiconductor device according to an embodiment includes a memory cell region CELL and a peripheral circuit region PERI.

The memory cell region CELL may include a cell substrate 100, an insulating substrate 101, mold structures MS1 and MS2, interlayer insulating films 140a and 140b, a channel structure CH, a channel pad 136, a block separation region WCf, a bit line BL, a cell contact 162, a source contact 164, a through line 166, and a first wiring structure 180.

For example, the cell substrate 100 may include a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate, etc. In some embodiments, the cell substrate 100 may include impurities. For example, the cell substrate 100 may include p-type impurities (e.g., boron (B), aluminum (Al), gallium (Ga), etc.). As another example, the cell substrate 100 may include n-type impurities (e.g., phosphorus (P), arsenic (As), etc.).

The cell substrate 100 may include a cell array region CAR and an extension region EXT.

A memory cell array (e.g., MA of FIG. 1) including a plurality of memory cells may be formed in the cell array region CAR. For example, the channel structure CH, the bit line BL, gate layers ECL, GSL1, GSL2, WL11 to WLIn, WL21 to WL2n, SSL1, SSL2, etc. may be disposed in the cell array region CAR. In the following description, the surface of the cell substrate 100 on which the memory cell array is disposed may be referred to as a front side of the cell substrate 100. The surface of the cell substrate 100 opposite to the front side of the cell substrate 100 may be referred to as a back side of the cell substrate 100.

The extension region EXT may be disposed in a peripheral region of the cell array region CAR. The gate layers ECL, GSL1, GSL2, WL11 to WL1n, WL21 to WL2n, SSL1, SSL2 may be stacked in the extension region EXT.

In some embodiments, the cell substrate 100 may further include a through region THR. The through region THR may be disposed inside the cell array region CAR and the extension region EXT, or may be disposed outside the cell array region CAR and the extension region EXT. The through line 166 may be disposed in the through region THR.

The insulating substrate 101 may be formed in the cell substrate 100 of the extension region EXT. The insulating substrate 101 may form an insulating region in the cell substrate 100 of the extension region EXT. For example, the insulating substrate 101 may include at least one of silicon oxide, silicon nitride, silicon oxynitride, and silicon carbide, but embodiments are not limited thereto. In some embodiments, the insulating substrate 101 may also be formed in the cell substrate 100 of the through region THR.

It is illustrated that a lower surface of the insulating substrate 101 is disposed coplanar with a lower surface of the cell substrate 100, but this is merely an example. As another example, the lower surface of the insulating substrate 101 may be lower than the lower surface of the cell substrate 100.

The mold structures MS1 and MS2 may be formed on the front side of the cell substrate 100. The mold structures MS1 and MS2 may include a plurality of gate layers ECL, GSL1, GSL2, WL11 to WL1n, WL21 to WL2n, SSL1, SSL2 and a plurality of insulating layers 110 and 115 stacked on the cell substrate 100. Each of the gate layers ECL, GSL1, GSL2, WL11 to WL1n, WL21 to WL2n, SSL1, SSL2 and each of the insulating layers 110 and 115 may have a layered structure extending parallel to the front side of the cell substrate 100. The gate layers ECL, GSL1, GSL2, WL11 to WL1n, WL21 to WL2n, SSL1, SSL2 may be stacked in order on the cell substrate 100 and spaced apart from each other by the plurality of insulating layers 110 and 115.

In some embodiments, the mold structures MS1 and MS2 may include a first mold structure MS1 and a second mold structure MS2 which are stacked in order on the cell substrate 100. The first mold structure MS1 and the second mold structure MS2 may be referred to as a “lower mold structure” and an “upper mold structure”, respectively. Any configuration X included in the first mold structure MS1 may be referred to as a “lower X”, and any configuration Y included in the second mold structure MS2 may be referred to as an “upper Y”.

The first mold structure MS1 may include first gate layers ECL, GSL1, GSL2, and WL11 to WL1n and first insulating layers 110 alternately stacked on the cell substrate 100. In some embodiments, the first gate layers ECL, GSL1, GSL2, and WL11 to WL1n may include the erase control line ECL, the ground select lines GSL1 and GSL2, and a plurality of first word lines WL11 to WlIn, which are stacked in order on the cell substrate 100. The ground select lines GSL1 and GSL2 may include a first ground select line GSL1 and a second ground select line GSL2 that are stacked in order. Although it is illustrated that the first gate layers ECL, GSL1, GSL2, and WL11 to WL1n include only two ground select lines GSL1 and GSL2, this is only an example. For example, the first gate layers ECL, GSL1, GSL2, and WL11 to WL1n may include three or more ground select lines or one ground select line. In some other embodiments, the erase control line ECL may be omitted.

The second mold structure MS2 may include the second gate layers WL21 to WL2n, SSL1, SSL2 and the second insulating layers 115, etc., which are alternately stacked on the first mold structure MS1. In some embodiments, the second gate layers WL21 to WL2n, SSL1, SSL2 may include a plurality of second word lines WL21 to WL2n and string select lines SSL1 and SSL2, which are stacked in order on the first mold structure MS1. The string select lines SSL1 and SSL2 may include a first string select line SSL1 and a second string select line SSL2, which are stacked in order. Although it is illustrated that the second gate layers WL21 to WL2n, SSL1, SSL2 include only two string select lines SSL1 and SSL2, this is only an example. For example, the second gate layers WL21 to WL2n, SSL1, SSL2 may include three or more string select lines or one string select line.

Each of the gate layers ECL, GSL1, GSL2, WL11 to WL1n, WL21 to WL2n, SSL1, SSL2 may include a conductive material such as a metal such as tungsten (W), cobalt (Co), nickel (Ni), or a semiconductor material such as silicon, but embodiments are not limited thereto.

Each of the plurality of insulating layers 110 and 115 may include an insulating material such as at least one of silicon oxide, silicon nitride, and silicon oxynitride, but embodiments are not limited thereto.

In some embodiments, the mold structures MS1 and MS2 of the through region THR may include a plurality of mold sacrificial films 112 and 117 and the plurality of insulating layers 110 and 115, which are alternately stacked on the cell substrate 100 and/or the insulating substrate 101. Each of the mold sacrificial films 112 and 117 and each of the insulating layers 110 and 115 may have a layered structure extending parallel to an upper surface of the cell substrate 100. The mold sacrificial films 112 and 117 may be stacked in order on the cell substrate 100 and spaced apart from each other by the plurality of insulating layers 110 and 115.

In some embodiments, the first mold structure MS1 of the through region THR may include the first mold sacrificial films 112 and the first insulating layers 110, which are alternately stacked on the cell substrate 100, and the second mold structure MS2 of the through region THR may include the second mold sacrificial films 117 and the second insulating layers 115, which are alternately stacked on the first mold structure MS1.

Each of the mold sacrificial films 112 and 117 may include an insulating material, for example, at least one of silicon oxide, silicon nitride, and silicon oxynitride, but embodiments are not limited thereto. In some embodiments, the mold sacrificial films 112 and 117 may include a material having etch selectivity with respect to the plurality of insulating layers 110 and 115. For example, the material of the mold sacrificial films 112 and 117 may be chosen such that it can be selectively etched or removed and the material of the insulating layers 110 and 115 may be chosen so that it can resist etching. For example, the plurality of insulating layers 110 and 115 may include silicon oxide, and the mold sacrificial films 112 and 117 may include silicon nitride.

The interlayer insulating films 140a and 140b may be formed on the cell substrate 100 to cover the mold structures MS1 and MS2. In some embodiments, the interlayer insulating films 140a and 140b may include a first interlayer insulating film 140a and a second interlayer insulating film 140b, which are stacked in order on the cell substrate 100. The first interlayer insulating film 140a may cover the first mold structure MS1, and the second interlayer insulating film 140b may cover the second mold structure MS2. For example, the interlayer insulating films 140a and 140b may include at least one of silicon oxide, silicon oxynitride, and a low-k material having a dielectric constant lower than that of silicon oxide, but embodiments are not limited thereto.

The channel structure CH may be formed in the mold structures MS1 and MS2 of the cell array region CAR. In an embodiment, the channel structure CH serves as a conduction path for electric current within transistors that make up the memory cells. The channel structure CH may extend through the mold structures MS1 and MS2 in a vertical direction (hereinafter, referred to as a third direction Z) intersecting the upper surface of the cell substrate 100. For example, the channel structure CH may have a pillar shape (e.g., cylindrical shape) extending in the third direction (Z). For example, the channel structure CH may take the form of a vertical column extending through the mold structures MS1 and MS2. Accordingly, the channel structure CH may intersect each of the gate layers ECL, GSL1, GSL2, WL11 to WL1n, WL21 to WL2n, SSL1, SSL2. In some embodiments, the channel structure CH may have a bent part between the first mold structure MS1 and the second mold structure MS2. For example, the channel structure CH need not extend in a straight line vertically through the mold structures MS1 and MS2. For example, a portion of the channel structure may change direction such as curving or angling between MS1 and MS2.

The channel pad 136 may be disposed on the channel structure CH. The channel pad 136 may cover an upper portion of the channel structure CH. For example, the channel pad 136 may include polysilicon doped with impurities, but embodiments are not limited thereto. The channel pad 136 may be in contact with a bit line contact 182 and electrically connected to the bit line contact 182.

In some embodiments, the plurality of channel structures CH may be arranged in a zigzag form. For example, the plurality of channel structures CH may be arranged to cross each other in the first direction X and the second direction Y which are parallel to the upper surface of the cell substrate 100. The plurality of channel structures CH disposed in the zigzag form may further increase the degree of integration of the semiconductor device. In some embodiments, the plurality of channel structures CH may be disposed in a honeycomb form, as illustrated in FIG. 2.

In some embodiments, a dummy channel structure DCH may be formed in the mold structures MS1 and MS2 of the extension region EXT. The dummy channel structure DCH may be formed in a shape similar to that of the channel structure CH to reduce stress applied to the mold structures MS1 and MS2 in the extension region EXT. In an embodiment, a dummy channel structure DCH does not perform any active or functional role like the channel structure CH.

In some embodiments, first source structures 102 and 104 may be formed on the cell substrate 100. The first source structures 102 and 104 may be provided as a common source line (e.g., CSL of FIG. 1) of the semiconductor device. For example, the first source structures 102 and 104 may include polysilicon or metal doped with impurities, but embodiments are not limited thereto.

In some embodiments, the first source structures 102 and 104 may include multiple layers. For example, the first source structures 102 and 104 may include a first source layer 102 and a second source layer 104, which are stacked in order on the cell substrate 100. Each of the first source layer 102 and the second source layer 104 may include polysilicon doped with impurities or polysilicon undoped with impurities, but embodiments are not limited thereto. The first source layer 102 may be provided as a common source line (e.g., CSL of FIG. 2) of the semiconductor device. The second source layer 104 may be used as a support layer for preventing the mold stack from collapsing or falling in a replacement process for forming the first source layer 102.

A base insulating film may be interposed between the cell substrate 100 and the first source structures 102 and 104. For example, the base insulating layer may include at least one of silicon oxide, silicon nitride, and silicon oxynitride, but is not limited thereto.

In some embodiments, the first source structures 102 and 104 are not formed in the extension region EXT in which the insulating substrate 101 is formed. It is illustrated that the upper surface of the insulating substrate 101 is disposed coplanar with the upper surfaces of the first source structures 102 and 104, but this is merely an example. As another example, the upper surface of the insulating substrate 101 may be higher than the upper surfaces of the first source structures 102 and 104.

In some embodiments, a source sacrificial film 103 may be formed on a portion of the cell substrate 100. For example, the source sacrificial film 103 may be formed on a portion of the cell substrate 100 in the extension region EXT. The source sacrificial film 103 may include a material having etch selectivity with respect to the plurality of insulating layers 110 and 115. For example, the plurality of insulating layers 110 and 115 may include silicon oxide, and the source sacrificial film 103 may include silicon nitride. The source sacrificial film 103 may be a layer remaining after a portion of the first source structures 102 and 104 is replaced with the first source layer 102 in the manufacturing process thereof.

The block separation region WCf, a first partial separation region WC1, and a second partial separation region WC2 may each extend in the first direction X to cut the mold structures MS1 and MS2. The block separation region WCf may completely cut through the mold structures MS1 and MS2. For example, the block separation region WCf may extend continuously in the first direction X. The first partial separation region WC1 and the second partial separation region WC2 may each partially cut the mold structures MS1 and MS2. For example, a row of the first partial separation regions WC1 arranged along the first direction X may be spaced apart from each other to partially cut the mold structures MS1 and MS2, and a row of the second partial separation regions WC2 arranged along the first direction X may be spaced apart from each other to partially cut the mold structures MS1 and MS2.

The string separation structure SC may extend in the first direction X to cut the string select lines SSL1 and SSL2. For example, the string separation structure SC formed in a first cell block BLK1 may divide the string select lines SSL1 and SSL2 into a first zone I and a second zone II, respectively. Accordingly, the first string select line SSL1 of the first zone I and the first string select line SSL1 of the second zone II may be separated and controlled separately, and the second string select line SSL2 of the first zone I and the second string select line SSL2 of the second zone II may be separated and controlled separately.

The string separation structure (SC) may include an insulating material, for example, at least one of silicon oxide, silicon nitride, and silicon oxynitride, but embodiments are not limited thereto.

The bit line BL may be formed on the mold structures MS1 and MS2. The bit line BL may extend in the second direction Y and intersect the block separation region WCf. In addition, the bit line BL may extend in the second direction Y and be connected to a plurality of channel structures CH arranged along the second direction Y. For example, the bit line contact 182 connected to an upper portion of each of the channel structures CH may be formed in the second interlayer insulating film 140b. The bit line BL may be electrically connected to the channel structures CH through the bit line contact 182.

The cell contact 162 may be connected to each of the gate layers ECL, GSL1, GSL2, WL11 to WL1n, WL21 to WL2n, SSL1, SSL2. For example, the cell contact 162 may extend in the third direction Z in the interlayer insulating films 140a and 140b and be connected to each of the gate layers ECL, GSL1, GSL2, WL11 to WL1n, WL21 to WL2n, SSL1, SSL2. In some embodiments, the cell contact 162 may include a bent part between the first mold structure MS1 and the second mold structure MS2.

In some embodiments, the cell contact 162 may be connected to each of the gate layers ECL, GSL1, GSL2, WL11 to WL1n, WL21 to WL2n, SSL1, SSL2 through a stair-free contact method. For example, the gate layers ECL, GSL1, GSL2, WL11 to WL1n, WL21 to WL2n, SSL1, SSL2 and the insulating layers 110 and 115 may be alternately stacked in a planar shape in the first mold structure MS1 and the second mold structure MS2 of the extension region EXT, and the cell contact 162 may extend through at least a portion of the gate layers ECL, GSL1, GSL2, WL11 to WL1n, WL21 to WL2n, SSL1, SSL2 and through at least a portion of the insulating layers 110 and 115 of the first mold structure MS1 or the second mold structure MS2.

However, embodiments are not limited thereto, and may include a stair contact method as well as a stair-free contact method. For example, the gate layers ECL, GSL1, GSL2, WL11 to WL1n, WL21 to WL2n, SSL1, SSL2 and the insulating layers 110 and 115 may be alternately stacked in a stair step manner in the first mold structure MS1 and the second mold structure MS2 of the extension region EXT.

The cell contact 162 may include a plurality of first word line contacts CNT1 extending through the first mold structure MS1 and each being connected to any one of the plurality of first gate layers ECL, GSL1, GSL2, and WL11 to WL1n. Additionally, there may be a plurality of first through vias THV extending through the second mold structure MS2 and electrically connected to the plurality of first word line contacts CNT1.

Likewise, the cell contact 162 may include a plurality of second word line contacts CNT2 extending through the second mold structure MS2 and each being connected to any one of the plurality of second gate layers WL21 to WL2n, SSL1, SSL2.

Although FIG. 3 illustrates that there are four first word line contacts CNT1 and four second word line contacts CNT2, respectively, this is for convenience of description, and embodiments are not limited thereto. For example, the first word line contact CNT1 may be connected to some or all of the first gate layers ECL, GSL1, GSL2, and WL11 to WL1n, and the second word line contacts CNT2 may be connected to some or all of the plurality of second gate layers WL21 to WL2n, SSL1, SSL2.

The cell contacts 162 farther away from the cell array region CAR are not necessarily connected to the lower gate layer, and the cell contact 162 connected to each of the gate layers ECL, GSL1, GSL2, WL11 to WL1n, WL21 to WL2n, SSL1, SSL2 may be formed at any position in the first direction X.

The source contact 164 may be connected to the first source structures 102 and 104. For example, the source contact 164 may extend in the interlayer insulating films 140a and 140b in the third direction Z and be connected to the cell substrate 100. In some embodiments, the source contact 164 may include a bent part between the first mold structure MS1 and the second mold structure MS2.

The through line 166 may be disposed in the through region THR. For example, the through line 166 may extend in the third direction Z in the mold structures MS1 and MS2 of the through region THR. In some embodiments, the through line 166 includes a bent part between the first mold structure MS1 and the second mold structure MS2. Although it is illustrated that the through line 166 extends through the mold structures MS1 and MS2, this is only an example. As another example, the through line 166 may be disposed outside the mold structures MS1 and MS2 and does not extend through the mold structures MS1 and MS2.

The cell contact 162, the source contact 164, and the through line 166 may each be connected to the first wiring structure 180 on the interlayer insulating films 140a and 140b. For example, a first inter-wiring insulating film 142 may be formed on the second interlayer insulating film 140b. The first wiring structure 180 may be formed in the first inter-wiring insulating film 142. The cell contact 162, the source contact 164, and the through line 166 may each be connected to the first wiring structure 180 by a contact via 184. The first wiring structure 180 may be connected to the bit line BL.

The peripheral circuit region PERI may include a peripheral circuit substrate 200, a peripheral circuit element PT, and a second wiring structure 260.

The peripheral circuit substrate 200 may be disposed below the cell substrate 100. For example, the upper surface of the peripheral circuit substrate 200 may face the lower surface of the cell substrate 100. For example, the peripheral circuit substrate 200 may include a semiconductor substrate such as a silicon substrate, a germanium substrate, or a silicon-germanium substrate. Alternatively, the peripheral circuit substrate 200 may also include a silicon-on-insulator (SOI) substrate or a germanium-on-insulator (GOI) substrate, etc.

The peripheral circuit element PT may be formed on the peripheral circuit substrate 200. The peripheral circuit element PT may form a peripheral circuit that controls the operation of the semiconductor device. For example, the peripheral circuit element PT may include a control logic, a row decoder, a page buffer, etc. In the following description, the surface of the peripheral circuit substrate 200 on which the peripheral circuit element PT is disposed may be referred to as a front side of the peripheral circuit substrate 200. Further, the surface of the peripheral circuit substrate 200 opposite the front side of the peripheral circuit substrate 200 may be referred to as a back side of the peripheral circuit substrate 200.

For example, the peripheral circuit element PT may include a transistor, but embodiments are not limited thereto. For example, the peripheral circuit element PT may include not only various active elements such as transistors, but also various passive elements such as capacitors, resisters, and inductors.

In some embodiments, the back side of the cell substrate 100 may face the front side of the peripheral circuit substrate 200. For example, a second inter-wiring insulating film 240 covering the peripheral circuit element PT may be formed on the front side of the peripheral circuit substrate 200. The cell substrate 100 and/or the insulating substrate 101 may be stacked on an upper surface of the second inter-wiring insulating film 240.

The first wiring structure 180 may be connected to the peripheral circuit element PT through the through line 166. For example, the second wiring structure 260 connected to the peripheral circuit element PT may be formed in the second inter-wiring insulating film 240. The through line 166 may extend in the third direction Z and connect the first wiring structure 180 and the second wiring structure 260. Through this, the bit line BL, each of the gate layers ECL, GSL1, GSL2, WL11 to WL1n, WL21 to WL2n, SSL1, SSL2, and/or the first source structures 102 and 104 may be electrically connected to the peripheral circuit element PT.

In some embodiments, the through line 166 may extend through the insulating substrate 101 and connect the first wiring structure 180 and the second wiring structure 260. Through this, the through line 166 may be electrically separated from the cell substrate 100.

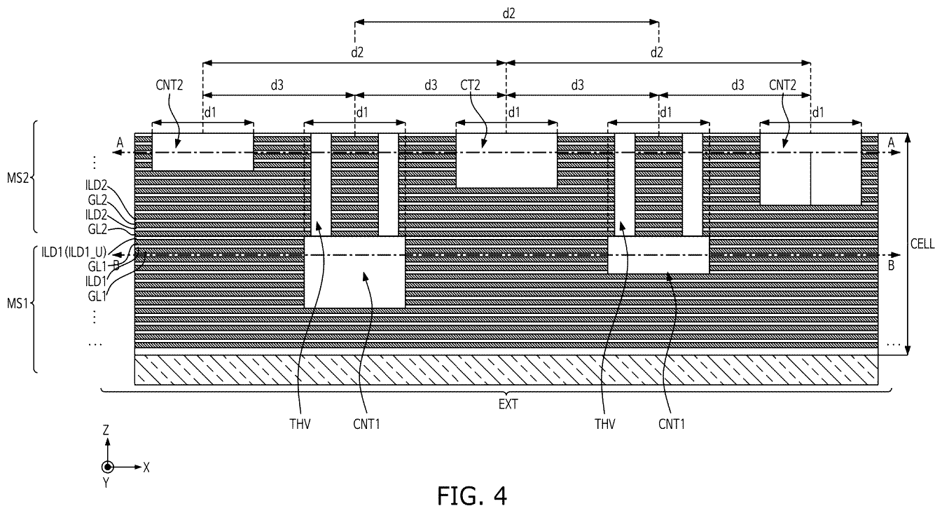

FIG. 3 schematically illustrates the arrangement of the cell contact 162, the connection between the cell contact 162 and each of the gate layers ECL, GSL1, GSL2, WL11 to WL1n, WL21 to WL2n, SSL1, SSL2, the connection between the first word line contact CNT1 and the first through via THV, etc. The specific arrangement of the cell contact 162, the connection between the cell contact 162 and other components, etc. will be described in detail below with reference to FIGS. 4 to 15.

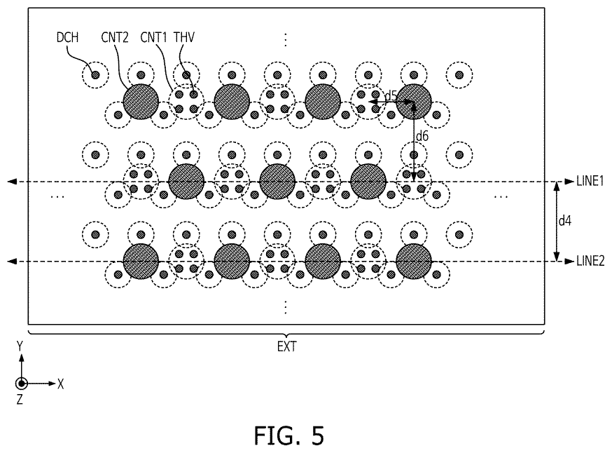

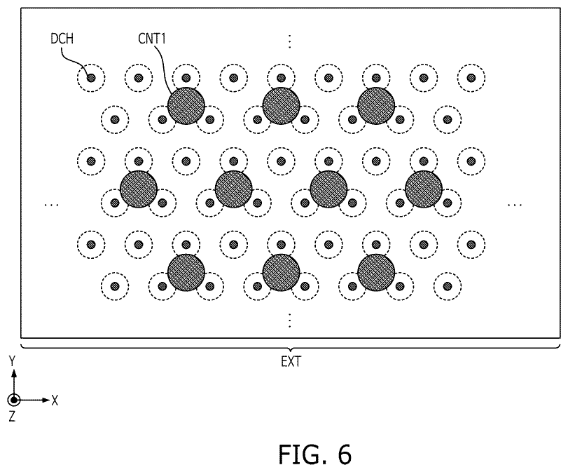

FIG. 4 is a cross-sectional view of the semiconductor device, FIG. 5 is a cross-sectional view taken along line A-A of FIG. 4, and FIG. 6 is a cross-sectional view taken along line B-B of FIG. 4. The semiconductor device illustrated in FIGS. 4 to 6 may correspond to the semiconductor device illustrated and described with reference to FIGS. 1 to 3. The cross-sectional views illustrated in FIGS. 4 to 6 are examples, and some components of the semiconductor device of FIGS. 1 to 3 may be omitted for convenience of description of various embodiments.

The semiconductor device may include the cell substrate 100, the first mold structure MS1, and the second mold structure MS2.

The first mold structure MS1 may include a plurality of first insulating layers ILD1 and a plurality of first gate layers GL1, which are alternately stacked. The plurality of first insulating layers ILD1 and the plurality of first gate layers GL1 of FIG. 4 may correspond to the first insulating layer 110 and the first gate layers ECL, GSL1, GSL2, and WL11 to WL1n of FIG. 3, respectively.

The second mold structure MS2 may include a plurality of second insulating layers ILD2 and a plurality of second gate layers GL2, which are alternately stacked. The plurality of second insulating layers ILD2 and the plurality of second gate layers GL2 of FIG. 4 may correspond to the second insulating layer 115 and the second gate layers WL21 to WL2n, SSL1, SSL2 of FIG. 3, respectively.

The plurality of first word line contacts CNT1 may extend through the first mold structure MS1 and may each be connected to any one of the plurality of first gate layers GL1. A plurality of through vias THV may extend through the second mold structure MS2 and be electrically connected to the plurality of first word line contacts CNT1. Although FIG. 5 illustrates that each of the plurality of through vias THV include four connection lines in a 2 by 2 arrangement, embodiments are not limited thereto. For example, the through vias THV may include any number of connection lines (e.g., any one of 1 to 3). In addition, if each of the plurality of through vias THV includes a plurality of connection lines, each of the plurality of connection lines may be arranged at any position.

The plurality of second word line contacts CNT2 may extend through the second mold structure MS2 and may each be connected to any one of the plurality of second gate layers GL2.

In an embodiment, each of the plurality of first word line contacts CNT1 and the plurality of second word line contacts CNT2 are formed to have the same diameter d1 (or cross-sectional area). The plurality of first word line contacts CNT1 and the plurality of second word line contacts CNT2 are illustrated has having a circular shape, but embodiments are not limited thereto. For example, the contacts may be formed to have a cross section of various shapes such as oval, square, etc.

Each of the plurality of first word line contacts CNT1 or each of the plurality of second word line contacts CNT2 may be spaced apart from each other by a predetermined separation distance d2. When it is assumed that the plurality of first word line contacts CNT1 extending through the first mold structure MS1 and the second mold structure MS2 are formed away from the plurality of second word line contacts CNT2 in the X direction in the absence of the through via THV, if the separation distance d2 between adjacent word line contacts CNT1 and CNT2 is reduced to less than a predetermined distance, there is a risk of excessive loss of the mask and the mold structure due to the rapid loss of the photoresist PR during the etching process. Therefore, in this case, the separation distance d2 should be equal to or greater than a minimum separation distance such that the loss of the photoresist PR during the etching process corresponds to a threshold. If the separation distance d2 between the adjacent word line contacts CNT1 and CNT2 is increased to avoid the loss of the mask and the mold structure, there is a risk that the degree of integration of the word line contacts in the extension region EXT may decrease.

Alternatively, as illustrated in FIG. 4, if the through via THV connected to the plurality of first word line contacts CNT1 is formed and each of the plurality of second word line contacts CNT2 is formed between each of the plurality of second word line contacts CNT2 formed by the separation distance d2 equal to or greater than the minimum separation distance, a separation distance d3 between adjacent word line contacts CNT1 and CNT2 in the X direction may decrease. For example, the separation distance d3 between the adjacent word line contacts CNT1 and CNT2 in the X direction may be approximately half of the separation distance d2 in the absence of the through via THV.

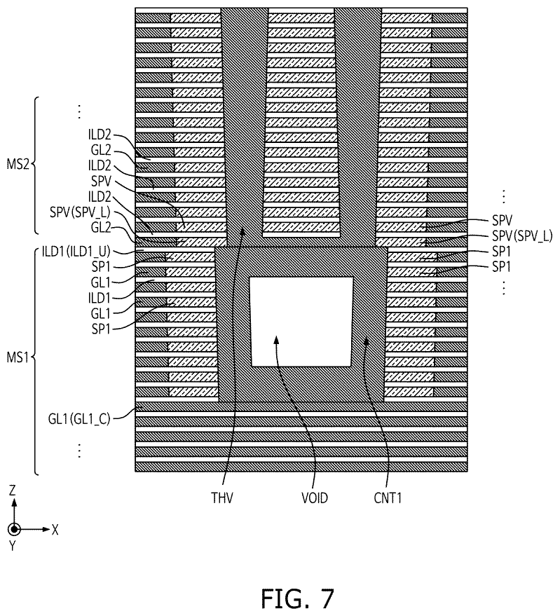

A detailed structure of one first word line contact CNT1, one through via THV, and one second word line contact CNT2 will be described in detail with reference to FIGS. 7 to 10.

Referring to FIG. 5, a plurality of through vias THV and the plurality of second word line contacts CNT2 may be disposed alternately one by one along the first direction X away from the cell array region CAR. For example, the plurality of through vias THV and the plurality of second word line contacts CNT2 may be disposed alternately one by one along a virtual first line LINE1 (or along a first line or in a first row) in the first direction X. Likewise, the plurality of second word line contacts CNT2 and the plurality of through vias THV may be disposed alternately one by one along a virtual second line LINE2 (or along a second line or in a second row) parallel to the virtual first line LINE1 and spaced apart at a predetermined interval d4.

Each of the plurality of through vias THV disposed in the first line LINE1 and each of the plurality of second word line contacts CNT2 disposed in the second line LINE2 may be disposed adjacent to each other. Likewise, each of the plurality of second word line contacts CNT2 disposed in the first line LINE1 and each of the plurality of through vias THV disposed in the second line LINE2 may be disposed adjacent to each other. As a result, each of the plurality of second word line contacts CNT2 may be surrounded by four adjacent through vias THV. Likewise, each of the through vias THV may be surrounded by four adjacent second word line contacts CNT2. For example, through vias THV may be vertically above, vertically below, horizontally to the left and horizontally to the right of a first word line contact CNT1 and a second word line contact CNT2.

The plurality of through vias THV and the plurality of second word line contacts CNT2 may be disposed alternately one by one at a first interval d5 along the first direction X. Meanwhile, the plurality of through vias THV and the plurality of second word line contacts CNT2 may be disposed alternately one by one at a second interval d6 along the second direction Y perpendicular to the first direction X. In an embodiment, the second interval d6 is greater than the first interval d5. In an alternative embodiment, the second interval d6 and the first interval d5 are substantially the same or the same as each other.

As illustrated in FIGS. 5 and 6, the plurality of first word line contacts CNT1 may be disposed in a honeycomb structure. That is, the plurality of first word line contacts CNT1 may be disposed in a manner in which each of the plurality of first word line contacts CNT1 is positioned in the center of a hexagonal structure formed by six different first word line contacts, and a repeating pattern of the hexagonal structure formed by any six first word line contacts is formed. Likewise, the plurality of second word line contacts CNT2 may be disposed in a honeycomb structure. The hexagonal structure formed by any six word line contacts is not necessarily limited to a regular hexagonal structure.

As illustrated in FIGS. 5 and 6, a plurality of dummy channel structures DCH may be formed on the mold structures MS1 and MS2 in the extension region EXT. The dummy channel structure DCH of FIGS. 5 and 6 may correspond to the dummy channel structure DCH of FIG. 2, but embodiments are not limited thereto. For example, the dummy channel structure DCH of FIGS. 5 and 6 may be different from the arrangement of the dummy channel structure DCH of FIG. 2. Spacers may be formed around each of the dummy channel structures DCH.

A dotted line surrounding the dummy channel structure DCH of FIGS. 5 and 6 may indicate a range in which the dummy channel structure DCH can be extended on the XY plane. For example, the dummy channel structure DCH may have a range indicated by a solid line on the XY plane at the same level as the plurality of first insulating layers ILD1 of the first mold structure MS1 and the plurality of second insulating layers ILD2 of the second mold structure MS2. In addition, the dummy channel structure DCH may have a dotted-lined range on the XY plane at the same level as the plurality of first gate layers GL1 of the first mold structure MS1 and the second gate layer GL2 of the second mold structure MS2. In an embodiment of the present disclosure, at the same level means being disposed at the same height in a vertical direction (hereinafter, referred to as the third direction Z) intersecting the upper surface of the cell substrate 100. The expression “same” as used herein may mean substantial sameness that includes manufacturing tolerances.

FIG. 7 is a diagram illustrating in detail structures of the first word line contact CNT1 and the through via THV of FIG. 4 according to an embodiment. As illustrated, an upper end of the first word line contact CNT1 may correspond to an uppermost insulating layer ILD1_U of the plurality of first insulating layers ILD1. For example, the upper end of the first word line contact CNT1 may be substantially at the same level as the upper end of the uppermost insulating layer ILD1_U. A lower end of the first word line contact CNT1 may correspond to a first gate layer GL1_C connected to the first word line contact CNT1 of the plurality of first gate layers GL1. For example, the lower end of the first word line contact CNT1 may be substantially at the same level as an upper end of the first gate layer GL1_C.

In an embodiment, a void VOID is formed in at least a portion of the first word line contact CNT1. The void VOID may have various shapes. FIG. 7 illustrates a void VOID that is rectangular in cross section as an example, but embodiments are not limited thereto. For example, the void VOID may be in the shape of a water droplet, a triangle, or any polygon in cross section. Additionally, a void may be further formed in at least a portion of the through via THV (e.g., in an upper middle part of the through via THV). The first word line contact CNT1 is not limited to the shape illustrated in FIG. 7, and may be formed without a void VOID. In an embodiment, the void VOID is an empty space or empty volume filled with a gas such as air or may be a vacuum including no gas or a near-vacuum.

In an embodiment, the diameter (or cross-sectional area) of the first word line contact CNT1 progressively decreases from upper to lower end of the first word line contact CNT1. In an alternate embodiment, the diameter (or cross-sectional area) of the first word line contact CNT1 is the same or substantially the same at all heights.

The through via THV may include any number of connection lines. A plurality of connection lines of the through via THV may be spaced apart from each other at equal intervals or may be formed to extend through the second mold structure MS2 in a Z-axis direction from any point on the circumference of the virtual circle on the XY plane.

In an embodiment, the diameter (or cross-sectional area) of the through via THV progressively decreases from upper to lower end. In an alternate embodiment, the diameter (or cross-sectional area) of the through via THV is the same or substantially the same at all heights.

One or more first spacers SP1 and a plurality of via spacers SPV may be formed to insulate between the first word line contact CNT1 and the through via THV and other gate layers except for the first gate layer GL1_C to which the first word line contact CNT1 is electrically connected.

At least one first spacer SP1 may be formed to surround a side surface of the first word line contact CNT1. The one or more first spacers SP1 may be disposed between one or more gate layers and the first word line contact CNT1 positioned at a higher level than the first gate layer GL1_C to which the first word line contact CNT1 is electrically connected.

The plurality of via spacers SPV may be formed to surround a side surface of the through via THV. The plurality of via spacers SPV may be disposed between the plurality of second gate layers GL2 and the through via THV.

As illustrated in FIG. 7, the through via THV may be spaced inward from an upper edge of the first word line contact CNT1 and connected to the first word line contact CNT1. For example, the through via THV may be positioned in an interior of the second mold structure MS2 above the upper edge of the first word line contact CNT1. In addition, the lowermost via spacer SPV_L of the plurality of via spacers SPV may cover a region spanning from at least the through via THV to the upper edge of the first word line contact CNT1 in an outward direction. For example, the lowermost via spacer SPV_L may cover an outer side of the through via THV and cover an upper side of the first word line contact CNT1. Through this, it is possible to prevent a short circuit from occurring between the gate layer positioned at the same level as the lowermost via spacer SPV_L and the first word line contact CNT1.

For example, the first word line contact CNT1 and/or the second word line contact CNT2 may include at least one of a conductive metal material (cobalt (Co), titanium (Ti), nickel (Ni), tungsten (W), molybdenum (Mo), etc.), a metal nitride (titanium nitride (TiN), titanium silicon nitride (TiSiN), titanium aluminum nitride (TiAIN), tantalum aluminum nitride (TaAlN), tungsten nitride (WN), etc.), a noble metal material (platinum (Pt), ruthenium (Ru), iridium (Ir), etc.), a conductive oxide film (PtO, RuO₂, IrO₂, SrRuO₃ (SRO), (Ba,Sr) RuO₃ (BSRO), CaRuO₃ (CRO), LSCo, etc.), and a metal silicide film. However, embodiments are not limited to the above.

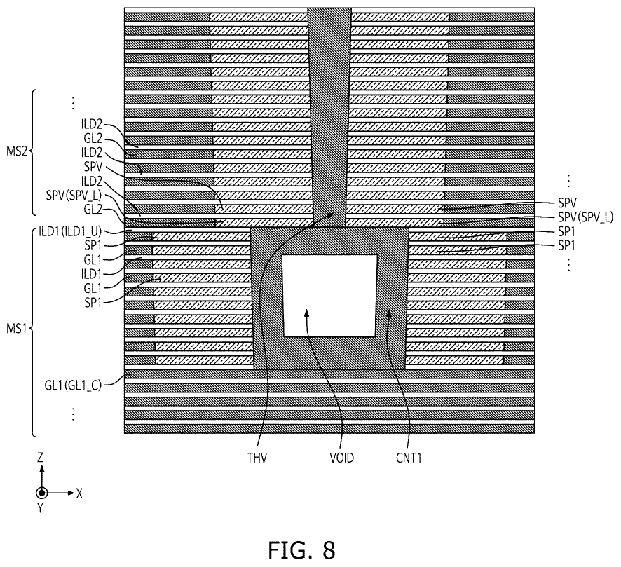

FIG. 8 is a diagram illustrating another example of the through via THV of FIG. 7. Unlike the example illustrated and described with reference to FIG. 7, the through via THV includes one connection line. For example, the through via THV of FIG. 7 may have two connection lines. In FIG. 8, the one connection line may be disposed to be connected to a center of the first word line contact CNT1.

In an embodiment, the first spacer SP1 and the via spacer SPV of FIG. 8 have the same length in the X direction. The expression “same” as used herein may mean the substantial sameness that includes manufacturing tolerances. According to another embodiment, the first spacer SP1 and the via spacer SPV of FIG. 8 have different lengths in the X direction.

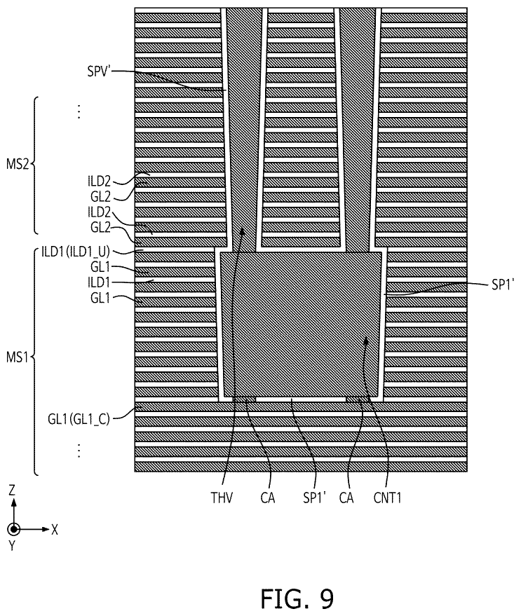

FIG. 9 is a view illustrating a modified example of the spacers SP1 and SPV of FIG. 7. The first spacer SP1′ and the via spacer SPV′ of FIG. 9 may be formed to insulate between the first word line contact CNT1 and the through via THV and other gate layers except for the first gate layer GL1_C to which the first word line contact CNT1 is electrically connected, and may also be formed to have a structure different from that of the spacers SP1 and SPV of FIG. 7.

The first spacer SP1′ of FIG. 9 may be formed to surround a portion of a side surface and a lower surface of the first word line contact CNT1. The first spacer SP1′ may be integrally formed. The first spacer SP1′ may be disposed between the first word line contact CNT1 and one or more gate layers and one or more insulating layers of the plurality of second gate layers GL1 and the plurality of second insulating layers ILD1, which are positioned at a higher level than the first gate layer GL1_C to which the first word line contact CNT1 is electrically connected.

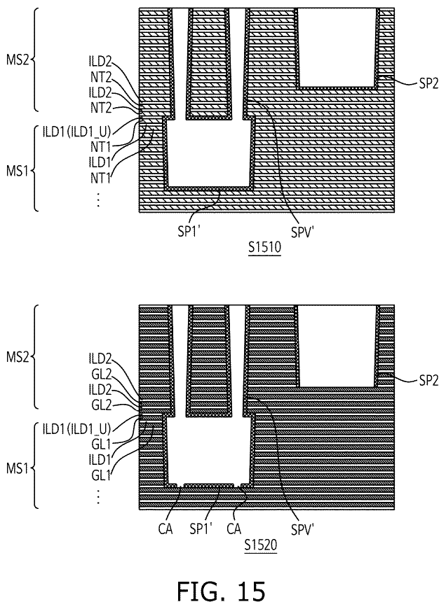

A hole corresponding to the contact region CA electrically connected to the first gate layer GL1_C may be formed on a lower surface of the first spacer SP1′. The position of the contact region CA or the hole may correspond to the position of the through via THV. For example, the width of the contact region CA or the hole in the X direction may at least partially overlap the width of the through via THV in the X direction. A process of forming the hole corresponding to the contact region CA will be described below in detail with reference to FIG. 15.

The via spacer SPV′ of FIG. 9 may be formed to surround the side surface of the through via THV. The via spacer SPV′ may be integrally formed on each of one or more connection lines of the through via THV. Additionally, the via spacer SPV′ may be integrally formed with the first spacer SP1′.

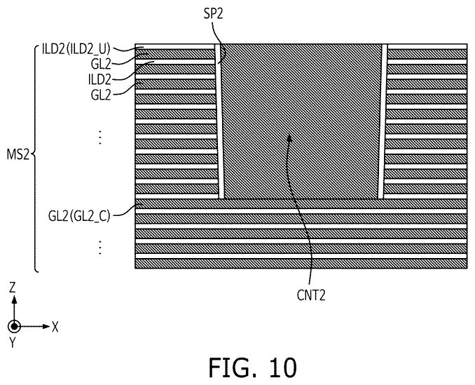

FIG. 10 is a diagram illustrating an embodiment of the second word line contact CNT2 of FIG. 4 in detail.

An upper end of the second word line contact CNT2 may correspond to an uppermost insulating layer ILD2_U of the plurality of second insulating layers ILD2. A lower end of the second word line contact CNT2 may correspond to a second gate layer GL2_C connected to the second word line contact CNT2 of the plurality of second gate layers GL2. For example, the upper end of the second word line contact CNT2 may be substantially at the same level as the upper end of the uppermost insulating layer ILD2_U, and the lower end of the second word line contact CNT2 may be substantially at the same level as the upper end of the second gate layer GL2_C.

In an embodiment, a diameter (or cross-sectional area) of the second word line contact CNT2 progressively decreases from upper to lower end of the second word line contact CNT2. In an alternate embodiment, the diameter (or cross-sectional area) of the second word line contact CNT2 is the same or substantially the same at all heights.

A second spacer SP2 may be integrally formed to surround a side surface of the second word line contact CNT2. The second spacer SP2 may be disposed between the second word line contact CNT2 and one or more gate layers and one or more insulating layers of the plurality of second gate layers GL2 and the plurality of second insulating layers ILD2, which are positioned at a higher level than the second gate layer GL2_C to which the second word line contact CNT2 is electrically connected.

It should be understood that the embodiments described above with reference to FIGS. 7 to 10 should not be understood as being necessarily applied collectively to all of the first word line contacts CNT1, all of the through vias THV, or all of the second word line contacts CNT2, and can be applied to some or all of the first word line contacts CNT1, some or all of the plurality of through vias THV, or some or all of the plurality of second word line contacts CNT2.

The spacers SP1, SP1′, SP2, SPV, and SPV′ may be a single layer, but may be a multilayer including a plurality of line spacers. The spacers SP1, SP1′, SP2, SPV, and SPV′ may include one of a silicon oxide film, a silicon nitride film, a silicon oxynitride film (SiON), a silicon oxycarbon nitride film (SiOCN), air, and a combination thereof, but embodiments are not limited thereto. At least some of the spacers SP1, SP1′, SP2, SPV, and SPV′ may include the same material, but embodiments are not limited thereto.

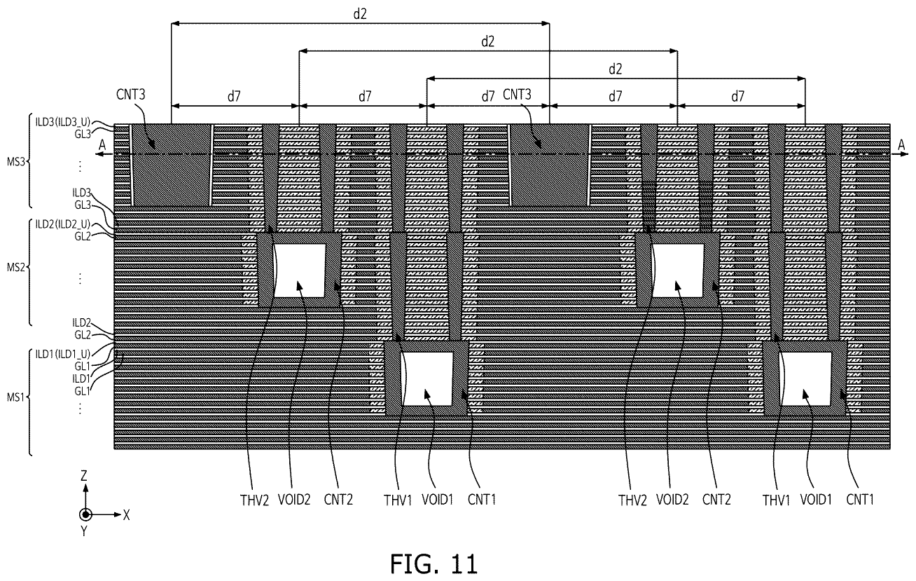

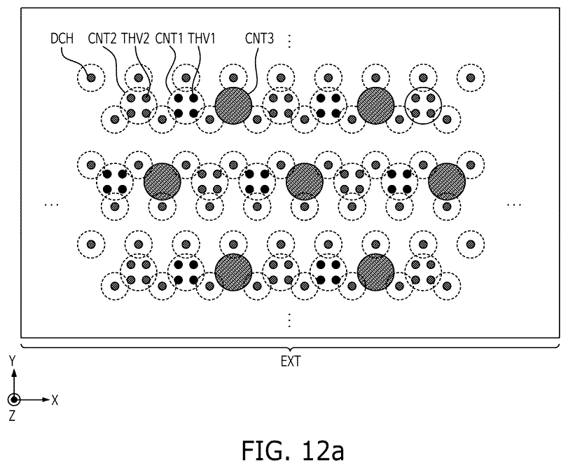

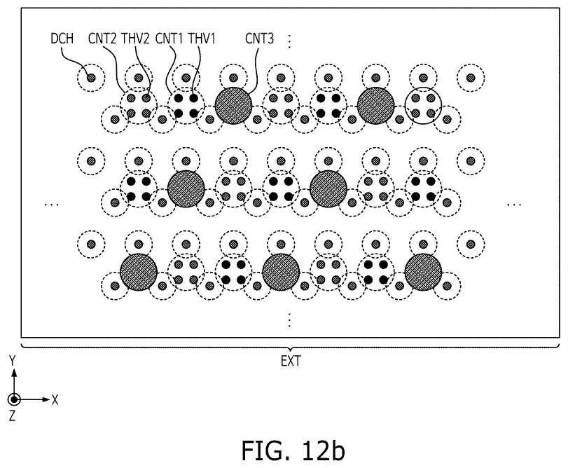

FIG. 11 is a cross-sectional view of the semiconductor device further including a third mold structure MS3, and FIGS. 12A and 12B are cross-sectional views taken along line A-A of FIG. 11 according to different embodiments. The third mold structure MS3 may be stacked on the second mold structure MS2, and may include a plurality of third insulating layers ILD3 and a plurality of third gate layers GL3, which are alternately stacked.

A plurality of third word line contacts CNT3 may extend through the third mold structure MS3, and may each be connected to any one of the plurality of third gate layers GL3.

A plurality of first through vias THV1 may extend through the second mold structure MS2 and the third mold structure MS3, and may be electrically connected to the plurality of first word line contacts CNT1. The plurality of first word line contacts CNT1 may extend through the first mold structure MS1, and may each be connected to any one of the plurality of first gate layers GL1.

A plurality of second through vias THV2 may extend through the third mold structure MS3 and may be electrically connected to the plurality of second word line contacts CNT2. The plurality of second word line contacts CNT2 may extend through the second mold structure MS2, and may each be connected to any one of the plurality of second gate layers GL2.

A plurality of third word line contacts CNT3 may extend through the third mold structure MS3, and may each be connected to any one of the plurality of third gate layers GL3.

Referring to FIGS. 12A and 12B, the plurality of third word line contacts CNT3, the plurality of second through vias THV2, and the plurality of first through vias THV1 may be disposed alternately one by one along the first direction X away from the cell array region CAR. A dotted line surrounding the dummy channel structure DCH of FIGS. 12A and 12B may indicate a range in which the dummy channel structure DCH can be extended on the XY plane.

Alternatively, the plurality of third word line contacts CNT3, the plurality of first through vias THV1, and the plurality of second through vias THV2 may be disposed alternately one by one in this order along the first direction X.

Through this, a separation distance d7 between the word line contacts CNT1, CNT2, and CNT3 adjacent to each other in the X direction may be reduced further than the separation distance d3 of FIG. 4. For example, the separation distance d3 between the word line contacts CNT1, CNT2, and CNT3 adjacent to each other in the X direction may be approximately ⅓ of the separation distance d2 in the absence of the through via THV.

FIGS. 11, 12A, and 12B illustrate three mold structures, but embodiments are not limited thereto. For example, the number of mold structures may be 4 or more, and a plurality of word line contacts may be disposed in each mold structure.

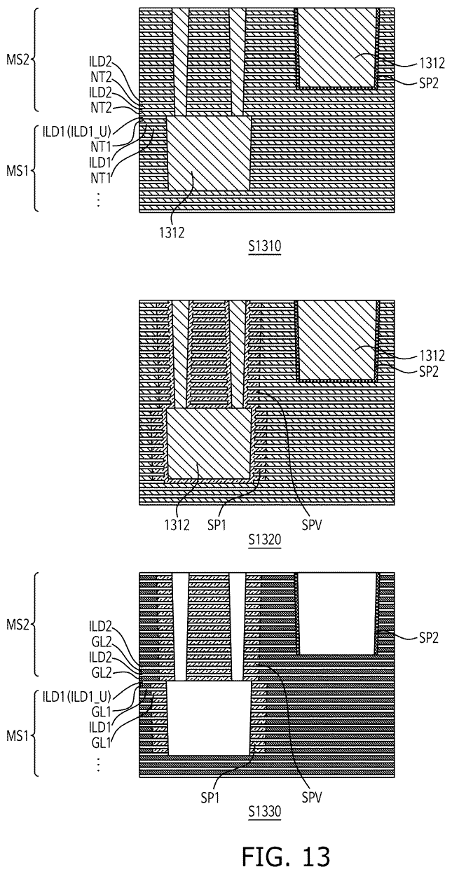

FIG. 13 is a diagram illustrating a method for manufacturing a semiconductor device according to an embodiment. Specifically, FIG. 13 is a diagram illustrating an example of a process of forming the first word line contact CNT1, the first spacer SP1, the through via THV, and the via spacer SPV of FIG. 7, and the second word line contact CNT2 and the second spacer SP2 of FIG. 10.

In a first operation at S1310, the first mold structure MS1 may include a plurality of first insulating layers ILD1 and a plurality of first nitride layers NT1, which are alternately stacked. Likewise, the second mold structure MS2 may include a plurality of second insulating layers ILD2 and a plurality of second nitride layers NT2, which are alternately stacked. Each of the plurality of first nitride layers NT1 and the plurality of second nitride layers NT2 are provided to form the plurality of first gate layers GL1 and the plurality of second gate layers GL2, and is not necessarily limited to a nitride component and may be replaced with a layer of other components.

In the first operation at S1310, the second spacer SP2 may be deposited on the second mold structure MS2. A sacrificial film 1312 may be deposited in a space in the first mold structure MS1 and the second mold structure MS2 where the word line contact and the through via are to be formed.

In a second operation at S1320, the first spacer SP1 and the via spacer SPV may be deposited. For example, after the space for the formation of the first spacer SP1 and the via spacer SPV is formed by wet etching in at least a portion of the plurality of first nitride layers NT1 and the plurality of second nitride layers NT2, the first spacer SP1 and the via spacer SPV may be deposited in the etched space. For example, the wet etching may be performed to remove portions of the nitride layers to create the etched space, and the spacers may be deposited in the etched space.

In a third operation at S1330, the plurality of first nitride layers NT1 and the plurality of second nitride layers NT2 may be replaced with the plurality of first gate layers GL1 and the plurality of second gate layers GL2, respectively. In addition, in the third operation at S1330, the lower surfaces of the first spacer SP1 and the second spacer SP2 may be etched such that the sacrificial film 1312 is removed and the word line contact is connected to any one of the plurality of first gate layers GL1 and any one of the plurality of second gate layers GL2, respectively.

A conductive material may be filled in the space leftover from removing the sacrificial film 1312. As a result, structures such as the first word line contact CNT1, the first spacer SP1, the through via THV, and the via spacer SPV of FIG. 7, and the second word line contact CNT2 and the second spacer SP2 of FIG. 10 may be formed.

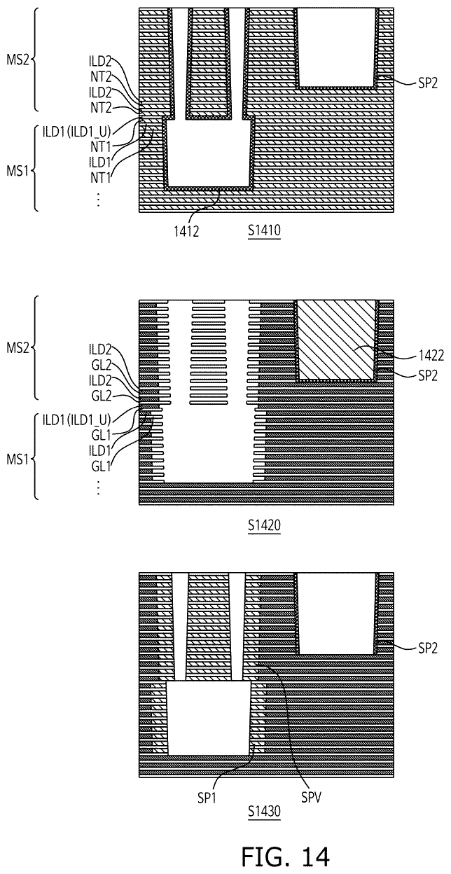

FIG. 14 is a diagram illustrating a method for manufacturing a semiconductor device according to an embodiment. Specifically, FIG. 14 is a diagram illustrating another example of a process of forming the first word line contact CNT1, the first spacer SP1, the through via THV, and the via spacer SPV of FIG. 7, and the second word line contact CNT2 and the second spacer SP2 of FIG. 10.

In a first operation at S1410, the first mold structure MS1 may include a plurality of first insulating layers ILD1 and a plurality of first nitride layers NT1, which are alternately stacked. Likewise, the second mold structure MS2 may include a plurality of second insulating layers ILD2 and a plurality of second nitride layers NT2, which are alternately stacked. Each of the plurality of first nitride layers NT1 and the plurality of second nitride layers NT2 are provided to form the plurality of first gate layers GL1 and the plurality of second gate layers GL2, and is not necessarily limited to a nitride component and may be replaced with a layer of other components.

In the first operation at S1410, a spacer 1412, SP2 may be deposited in a space in the first mold structure MS1 and the second mold structure MS2 where the word line contact and the through via are to be formed.

In a second operation at S1420, the plurality of first nitride layers NT1 and the plurality of second nitride layers NT2 may be replaced with the plurality of first gate layers GL1 and the plurality of second gate layers GL2, respectively. For example, the plurality of first gate layers GL1 and the plurality of second gate layers GL2 may be generated from the plurality of first nitride layers NT1 and the plurality of second nitride layers NT2, respectively.

In the second operation at S1420, a sacrificial film 1422 may be deposited in a space in the second mold structure MS2 where the word line contact is to be formed.

In the second operation at S1420, the spacer 1412 formed in the first mold structure MS1 and the second mold structure MS2 may be removed, and a space for the formation of the first spacer SP1 and the via spacer SPV may be formed by wet etching. For example, the wet etching may remove portions of the nitride layers to create an etched space.

In a third operation at S1430, the first spacer SP1 and the via spacer SPV may be deposited in the etched space formed in the second operation at S1420. The first spacer SP1 and the via spacer SPV may include nitride (e.g., SiN).

In the third operation at S1430, the lower surfaces of the first spacer SP1 and the second spacer SP2 may be etched such that the sacrificial film 1422 is removed and the word line contact is connected to any one of the plurality of first gate layers GL1 and any one of the plurality of second gate layers GL2, respectively.

A conductive material may be filled in the space leftover from removing the sacrificial film 1422, and in an inner space of the first spacer SP1 and the via spacer SPV. As a result, structures such as the first word line contact CNT1, the first spacer SP1, the through via THV, and the via spacer SPV of FIG. 7, and the second word line contact CNT2 and the second spacer SP2 of FIG. 10 may be formed.

FIG. 15 is a diagram illustrating a method for manufacturing a semiconductor device according to an embodiment. Specifically, FIG. 15 is a diagram illustrating an example of a process of forming the first word line contact CNT1, the first spacer SP1′, the through via THV, and the via spacer SPV′ of FIG. 9, and the second word line contact CNT2 and the second spacer SP2 of FIG. 10.

A first operation at S1510 may correspond to the first operation at S1410 of FIG. 14. The first spacer SP1′ and the via spacer SPV′ of the first operation at S1510 may correspond to the spacer 1412 of the first operation at S1410 of FIG. 14. For example, the first operation at S1410 may be performed here.

In a second operation at S1520, the plurality of first nitride layers NT1 and the plurality of second nitride layers NT2 may be replaced with the plurality of first gate layers GL1 and the plurality of second gate layers GL2, respectively. For example, the plurality of first gate layers GL1 and the plurality of second gate layers GL2 may be generated from the plurality of first nitride layers NT1 and the plurality of second nitride layers NT2, respectively.

In the second operation at S1520, a hole corresponding to the contact region CA may be formed on the lower surface of the first spacer SP1′.

The hole corresponding to the contact region CA may be formed, before the through via THV is formed, by performing plasma etching on the lower surface of the first spacer SP1′ through a region where the through via THV is to be formed. For example, a portion of the first spacer SP1′ may be removed through the plasma etching to form the hole.

A conductive material may be filled in an inner space of each of the spacers SP1′, SPV′, and SP2. As a result, structures such as the first word line contact CNT1, the first spacer SP1′, the through via THV and the via spacer SPV′ of FIG. 9 and the second word line contact CNT2 and the second spacer SP2 of FIG. 10 may be formed.

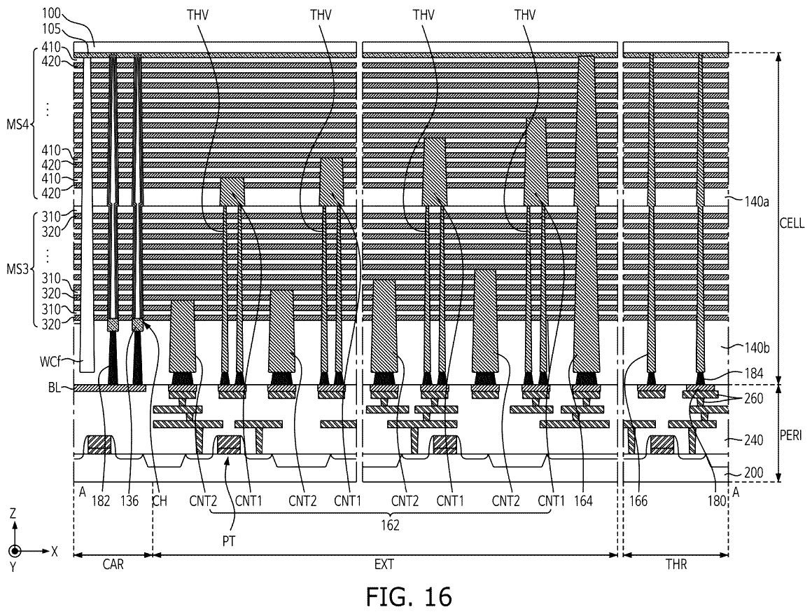

FIG. 16 is a cross-sectional view illustrating a semiconductor device according to an embodiment. FIG. 16 may be a cross-sectional view taken along line A-A of FIG. 2, or may be a cross-sectional view illustrating the semiconductor device according to an embodiment different from that of FIG. 3. For convenience of description, different configurations from those described in FIGS. 1 to 15 will be mainly described.

Referring to FIG. 16, the semiconductor device may include a cell structure CELL and a peripheral circuit region PERI. The cell structure CELL may be disposed above the peripheral circuit region PERI. The description of the peripheral circuit region PERI may be the same as that described above with reference to the other drawings.

A common source plate 105 may be disposed in the cell region CAR, the extension region EXT, and the through region THR. The common source plate 105 may be connected to the channel structure CH in the cell region CAR. For example, the common source plate 105 may be electrically connected to the semiconductor pattern of the channel structure CH. The common source plate 105 may be connected to the source contact 164 in the extension region EXT. The common source plate 105 may be connected to the through line 166 and the contact via 184 in the through region THR. The common source plate 105 may be provided as a common source line of the semiconductor memory device. For example, the common source plate 105 may include polycrystalline silicon or metal doped with impurities, but embodiments are not limited thereto.

The mold structures MS3 and MS4 may correspond to the mold structures MS2 and MS1 of FIG. 3. The fourth mold structure MS4 may be disposed on the cell array region CAR and the extension region EXT of the cell substrate 100. The fourth mold structure MS4 may include a plurality of insulating layers 410 and a plurality of gate layers 420, which are alternately stacked. Each of the insulating layers 410 and each of the gate layers 420 may have a layered structure extending parallel to the cell substrate 100. The gate layers 420 may be spaced apart from each other by the insulating layer 410 and stacked in order on the common source plate 105.

The third mold structure MS3 may be disposed on the fourth mold structure MS4. The third mold structure MS3 may include a plurality of insulating layers 310 and a plurality of gate layers 320, which are alternately stacked. An interlayer insulating film 140a may be disposed between the third mold structure MS3 and the fourth mold structure MS4. The interlayer insulating film 140a may cover a lower surface of the fourth mold structure MS4. The third mold structure MS3 may be formed on the interlayer insulating film 140a.

An interlayer insulating film 140b may be disposed on the third mold structure MS3. The interlayer insulating film 140b may cover a lower surface of the third mold structure MS3.

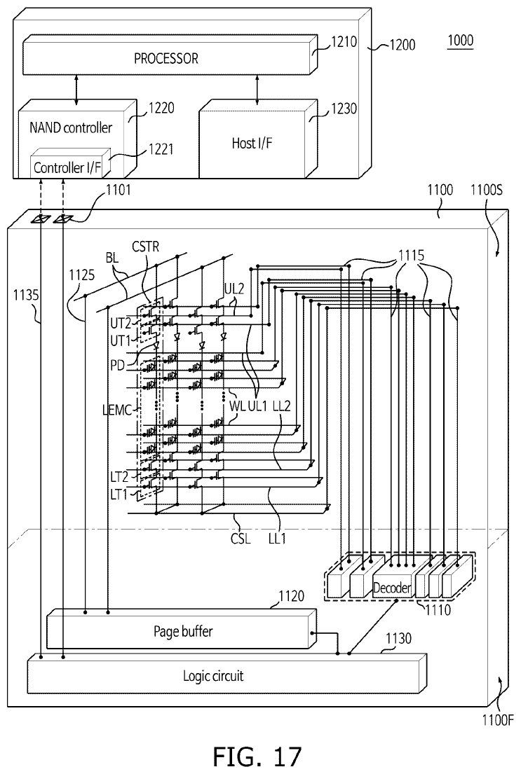

An electronic system including a semiconductor device according to at least one of the above-described embodiments will be described with reference to FIGS. 17, 18, and 19, respectively.

FIG. 17 is a diagram schematically illustrating an electronic system 1000 including a semiconductor device 1100.

Referring to FIG. 17, the electronic system (e.g., data storage system) 1000 may include the semiconductor device 1100 and a controller 1200 electrically connected to the semiconductor device 1100 to control the semiconductor device 1100. The electronic system 1000 may be a storage device including the semiconductor device 1100 or an electronic device including a storage device. For example, the electronic system 1000 may be a solid state drive device (SSD), a universal serial bus (USB), a computing system, a medical device, or a communication device including the semiconductor device 1100.

The electronic system 1000 may be an electronic system that stores data.

The semiconductor device 1100 may be a non-volatile memory device. For example, the semiconductor device 1100 may be the semiconductor device 1 according to any one of the embodiments described above with reference to FIGS. 1 to 16. The semiconductor device 1100 may include a first structure 1100F and a second structure 1100S on the first structure 1100F.

The first structure 1100F may be a peripheral circuit structure including a decoder circuit 1110, a page buffer 1120, and a logic circuit 1130. For example, the first structure 1100F may include the peripheral circuit structure PERI described above. The peripheral circuit element described above may be a transistor that may form the decoder circuit 1110, the page buffer 1120, and the logic circuit 1130.

The second structure 1100S may be a memory structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously modified according to embodiments.

In some embodiments, the upper transistors UT1 and UT2 may include a string select transistor SST, and the lower transistors LT1 and LT2 may include a ground select transistor GST. The gate lower lines LL1 and LL2 may each be gate electrodes of the lower transistors LT1 and LT2. The word lines WL may be the gate electrodes of the memory cell transistors MCT, and the gate upper lines UL1 and UL2 may be the gate electrodes of the upper transistors UT1 and UT2, respectively.

The gate layers GL described above may form the gate lower lines LL1 and LL2, the word lines WL, and the gate upper lines UL1 and UL2.

The common source line CSL, the first and second gate lower lines LL1 and LL2, the word lines WL, and the first and second gate upper lines UL1 and UL2 may be electrically connected to the decoder circuit 1110 through first connection lines 1115 extending from the first structure 1100F to the second structure 1100S.

The bit lines BL may be electrically connected to the page buffer 1120 through second connection wires 1125 extending from the first structure 1100F to the second structure 1100S. The bit lines BL may be the bit lines described above.

In the first structure 1100F, the decoder circuit 1110 and the page buffer 1120 may perform a control operation on at least one selected memory cell transistor MCT of the plurality of memory cell transistors MCT. The decoder circuit 1110 and the page buffer 1120 may be controlled by the logic circuit 1130.

The semiconductor device 1100 may further include an input and output pad 1101. The semiconductor device 1100 may communicate with the controller 1200 through the input and output pad 1101 electrically connected to the logic circuit 1130. The input and output pad 1101 may be electrically connected to the logic circuit 1130 through an input and output connection wiring 1135 extending from the first structure 1100F to the second structure 1100S. Accordingly, the controller 1200 may be electrically connected to the semiconductor device 1100 through the input and output pad 1101 and control the semiconductor device 1100.

The controller 1200 may include a processor 1210, a NAND controller 1220 (e.g., a controller circuit), and a host interface 1230 (e.g., an interface circuit). According to some embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may be operated according to a predetermined firmware, and may control the NAND controller 1220 to access the semiconductor device 1100. The NAND controller 1220 may include a NAND interface 1221 that processes communication with the semiconductor device 1100. A control command for controlling the semiconductor device 1100, data to be written in the memory cell transistors MCT of the semiconductor device 1100, data to be read from the memory cell transistors MCT of the semiconductor device 1100, etc. may be transmitted through the NAND interface 1221. The host interface 1230 may provide a communication function between the electronic system 1000 and an external host. Upon receiving a control command from the external host through the host interface 1230, the processor 1210 may control the semiconductor device 1100 in response to the control command.

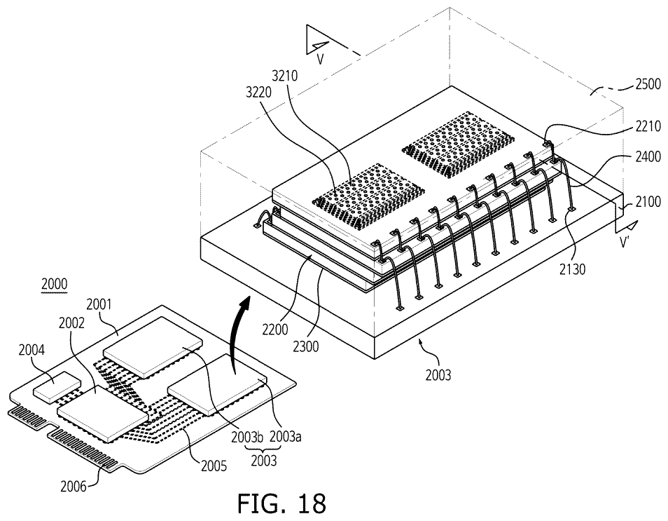

FIG. 18 is a perspective view schematically illustrating an electronic system including a semiconductor device according to at least one of the above-described embodiments.

Referring to FIG. 18, an electronic system 2000 (e.g., a data storage system) may include a main substrate 2001, a controller 2002 mounted on the main substrate 2001, one or more semiconductor packages 2003, and a DRAM 2004. The semiconductor packages 2003 and the DRAM 2004 may be connected to the controller 2002 by wiring patterns 2005 formed on the main substrate 2001.

The main substrate 2001 may include a connector 2006 including a plurality of pins coupled to an external host. The number and arrangement of the plurality of pins in the connector 2006 may vary according to a communication interface between the electronic system 2000 and the external host. In some examples, the electronic system 2000 may communicate with an external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some examples, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor packages 2003.

The controller 2002 may record data in the semiconductor packages 2003 or read data from the semiconductor packages 2003, and may increase the operation speed of the electronic system 2000.

The DRAM 2004 may be a buffer memory provided to alleviate the speed difference between an external host and the semiconductor packages 2003 as the data storage spaces. The DRAM 2004 included in the electronic system 2000 may also operate as a kind of cache memory, and may also provide a space for temporarily storing data in a control operation on the semiconductor packages 2003. If the electronic system 2000 includes the DRAM 2004, the controller 2002 may further include a DRAM controller for controlling the DRAM 2004, in addition to a NAND controller for controlling the semiconductor packages 2003.

The semiconductor packages 2003 may include first and second semiconductor packages 2003a and 2003b spaced apart from each other. Each of the first and second semiconductor packages 2003a and 2003b may be a semiconductor package including a plurality of semiconductor chips 2200. Each of the semiconductor chips 2200 may include the semiconductor device according to any one of the embodiments described above with reference to FIGS. 1 to 17.

Each of the first and second semiconductor packages 2003a and 2003b may include a package substrate 2100, the semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210.

In some examples, the connection structure 2400 may be a bonding wire electrically connecting the input and output pad 2210 and the package upper pads 2130. Therefore, in each of the first and second semiconductor packages 2003a and 2003b, the semiconductor chips 2200 may be electrically connected to each other with a bonding wire method, and may be electrically connected to the package upper pads 2130 of the package substrate 2100. In some examples, in each of the first and second semiconductor packages 2003a and 2003b, the semiconductor chips 2200 may be electrically connected to each other by a connection structure including through silicon via (TSV), instead of the bonding wire type connection structure 2400.

In some examples, the controller 2002 and the semiconductor chips 2200 may be included in one package. For example, the controller 2002 and the semiconductor chips 2200 may be mounted on a separate interposer substrate different from the main substrate 2001, and the controller 2002 and the semiconductor chips 2200 may be connected to each other by the wiring formed on the interposer substrate.

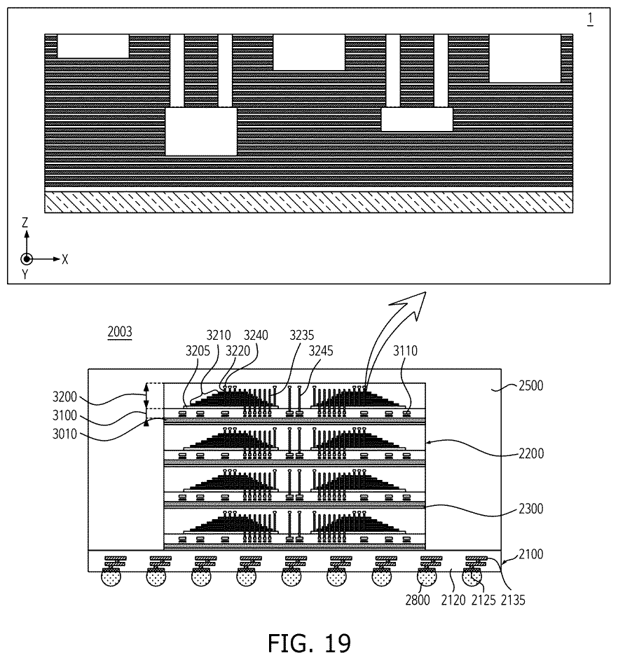

FIG. 19 is a cross-sectional view schematically illustrating a semiconductor package according to an embodiment. FIG. 19 illustrates an example embodiment of the semiconductor package 2003 of FIG. 18 and conceptually illustrates a region where the semiconductor package 2003 of FIG. 18 is cut along the cutting line V-V′.

Referring to FIGS. 18 and 19, in the semiconductor package 2003, the package substrate 2100 may be a printed circuit board. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of a main substrate 2010 of the electronic system 2000 through conductive connection portions 2800.

Each of the semiconductor chips 2200 may include a semiconductor substrate 3010, and a first structure 3100 and a second structure 3200 sequentially stacked on the semiconductor substrate 3010. The first structure 3100 may include a peripheral circuit area including peripheral wirings 3110. The second structure 3200 may include a common source line 3205, a stack structure 3210 on the common source line 3205, memory channel structures 3220 and isolation structures 3230 extending through the stack structure 3210, bit lines 3240 electrically connected to the memory channel structures 3220, and gate contact plugs electrically connected to word lines WL of the stack structure 3210. The first structure 3100 may include the first structure 1100F of FIG. 17, and the second structure 3200 may include the second structure 1100S of FIG. 17.

Each of the semiconductor chips 2200 may include a through wiring 3245 electrically connected to the peripheral wirings 3110 of the first structure 3100 and extending into the second structure 3200. The through wiring 3245 may extend through the stack structure 3210 and may be further disposed outside the stack structure 3210.

Each of the semiconductor chips 2200 may further include an input and output connection wiring 3265 electrically connected to the peripheral wirings 3110 of the first structure 3100 and extending into the second structure 3200, and an input and output pad (2210 in FIG. 19) electrically connected to the input and output connection wiring 3265.

In FIG. 19, referring to the partially enlarged illustration of the portion denoted by reference numeral 1, it is noted that the semiconductor chips 2200 of FIGS. 18 and 19 may be modified to include the partially enlarged portion of the structure in cross-section shown in FIG. 2. Accordingly, each of the semiconductor chips 2200 may include the semiconductor device 1 according to any one of the embodiments described above with reference to FIGS. 1 to 16.

Although certain embodiments of the present disclosure have been described with reference to the accompanying drawings, those of ordinary skill in the art to which the present disclosure pertains will understand that the present disclosure may be implemented in other specific forms without changing its technical idea. Therefore, it should be understood that the embodiments described above are illustrative and non-limiting in all respects.

What is claimed is:

1. A semiconductor device, comprising:
a substrate;
a first mold structure comprising a plurality of first insulating layers and a plurality of first gate layers which are alternately stacked on the substrate;
a second mold structure disposed on the first mold structure, comprising a plurality of second insulating layers and a plurality of second gate layers which are alternately stacked;
a plurality of first word line contacts extending through the first mold structure, wherein each of the first word line contacts is connected to a corresponding one of the plurality of first gate layers;
a plurality of second word line contacts extending through the second mold structure, wherein each of the second word line contacts is connected to a corresponding one of the plurality of second gate layers; and
a plurality of first through vias extending through the second mold structure and electrically connected to the plurality of first word line contacts.

2. The semiconductor device according to claim 1, wherein the plurality of first through vias and the plurality of second word line contacts are disposed alternately along a first direction away from a memory cell array region.

3. The semiconductor device according to claim 2, wherein
the plurality of first through vias and the plurality of second word line contacts are disposed alternately along a virtual first line in the first direction,
the plurality of second word line contacts and the plurality of first through vias are disposed alternately along a virtual second line parallel to the virtual first line and spaced apart at a predetermined interval,
each of the plurality of first through vias disposed in the first line and each of the plurality of second word line contacts disposed in the second line are disposed adjacent to each other, and
each of the plurality of second word line contacts disposed in the first line and each of the plurality of first through vias disposed in the second line are disposed adjacent to each other.

4. The semiconductor device according to claim 2, wherein
the plurality of first through vias and the plurality of second word line contacts are disposed alternately at a first interval along the first direction,
the plurality of first through vias and the plurality of second word line contacts are disposed alternately at a second interval along a second direction perpendicular to the first direction, and
the second interval is greater than the first interval.

5. The semiconductor device according to claim 1, wherein
the plurality of first word line contacts are arranged in a honeycomb structure in a plan view, and
the plurality of second word line contacts are arranged in a honeycomb structure in a plan view.

6. The semiconductor device according to claim 1, wherein each of the plurality of second word line contacts is surrounded by four adjacent first through vias.

7. The semiconductor device according to claim 1, wherein
the plurality of first word line contacts comprise a predetermined first word line contact,
a first upper end of the predetermined first word line contact corresponds to an uppermost insulating layer of the plurality of first insulating layers,
a first lower end of the predetermined first word line contact corresponds to a predetermined first gate layer, connected to the predetermined first word line contact, among the plurality of first gate layers,
the plurality of second word line contacts comprise a predetermined second word line contact,
a second upper end of the predetermined second word line contact corresponds to an uppermost insulating layer of the plurality of second insulating layers, and
a second lower end of the predetermined second word line contact corresponds to a predetermined second gate layer, connected to the predetermined second word line contact, among the plurality of second gate layers.

8. The semiconductor device according to claim 7, wherein
a diameter of the predetermined first word line contact progressively decreases from the first upper end to the first lower end, and
a diameter of the predetermined second word line contact progressively decreases from the second upper end to the second lower end.

9. The semiconductor device according to claim 7, wherein a void is present in at least a portion of the predetermined first word line contact.

10. The semiconductor device according to claim 1, wherein each of the plurality of first through vias comprises at least one connection line.

11. The semiconductor device according to claim 1, further comprising:
a third mold structure disposed on the second mold structure, comprising a plurality of third insulating layers and a plurality of third gate layers which are alternately stacked;
a plurality of third word line contacts extending through the third mold structure and each being connected to one of the plurality of third gate layers; and
a plurality of second through vias extending through the third mold structure and electrically connected to the plurality of second word line contacts, wherein
the plurality of first through vias further extend through the third mold structure.

12. The semiconductor device according to claim 11, wherein the plurality of third word line contacts, the plurality of second through vias, and the plurality of first through vias are disposed alternately along a first direction away from a memory cell array region.

13. The semiconductor device according to claim 1, wherein
the plurality of first word line contacts comprise a predetermined first word line contact,
the predetermined first word line contact is electrically connected to a predetermined first gate layer among the plurality of first gate layers,
the first mold structure further comprises at least one first spacer disposed between one or more gate layers positioned at a higher level than the predetermined first gate layer, and the predetermined first word line contact, and
the at least one first spacer are formed to surround a side surface of the predetermined first word line contact.

14. The semiconductor device according to claim 13, wherein
the plurality of first through vias comprise a predetermined first through via connected to the predetermined first word line contact,
the second mold structure further comprises a plurality of via spacers disposed between the plurality of second gate layers and the predetermined first through via, and
the plurality of via spacers are formed to surround a side surface of the predetermined first through via.

15. The semiconductor device according to claim 14, wherein
the predetermined first through via is spaced inward from an upper edge of the predetermined first word line contact and connected to the predetermined first word line contact, and
a lowermost via spacer of the plurality of via spacers covers a region spanning from at least the predetermined first through via to the upper edge of the predetermined first word line contact in an outward direction.

16. The semiconductor device according to claim 1, wherein
the plurality of first word line contacts comprise a predetermined first word line contact,
the predetermined first word line contact comprises a contact region electrically connected to a predetermined first gate layer among the plurality of first gate layers,
the first mold structure further comprises a first spacer integrally formed to surround a portion of a side surface and a lower surface of the predetermined first word line contact, and
a hole corresponding to the contact region is formed on a lower surface of the first spacer.

17. The semiconductor device according to claim 16, wherein
the plurality of first through vias comprise a predetermined first through via connected to the predetermined first word line contact, and
a position of the contact region in a plan view corresponds to a position of the predetermined first through via in the plan view.

18. The semiconductor device according to claim 1, wherein
the plurality of second word line contacts comprise a predetermined second word line contact,
the predetermined second word line contact is electrically connected to a predetermined second gate layer among the plurality of second gate layers,
the second mold structure further comprises a second spacer disposed between at least one gate layer of the plurality of second gate layers and at least one insulating layer of the plurality of second insulating layers which are positioned at a higher level than the predetermined second gate layer, and the predetermined second word line contact, and
the second spacer is integrally formed to surround a side surface of the predetermined second word line contact.

19. A semiconductor device, comprising:
a substrate;
a lower mold structure comprising a plurality of lower insulating layers and a plurality of lower gate layers which are alternately stacked on the substrate;
an upper mold structure disposed on the lower mold structure, comprising a plurality of upper insulating layers and a plurality of upper gate layers which are alternately stacked;
a plurality of lower word line contacts disposed at equal intervals along a predetermined direction in the lower mold structure, wherein each of the lower word line contact is connected to a corresponding one of the plurality of lower gate layers;
a plurality of upper word line contacts disposed at equal intervals along the predetermined direction in the upper mold structure, wherein each of the upper word line contacts is connected to a corresponding one of the plurality of upper gate layers; and
a plurality of through vias disposed at equal intervals along the predetermined direction in the upper mold structure, corresponding to the plurality of lower word line contacts in a plan view, and electrically connected to the plurality of lower word line contacts.

20. An electronic system, comprising:
a main substrate;
a semiconductor device disposed on the main substrate; and
a controller electrically connected to the semiconductor device on the main substrate, wherein
the semiconductor device comprises:
a substrate;
a first mold structure comprising a plurality of first insulating layers and a plurality of first gate layers which are alternately stacked on the substrate;
a second mold structure disposed on the first mold structure, comprising a plurality of second insulating layers and a plurality of second gate layers which are alternately stacked;
a plurality of first word line contacts extending through the first mold structure, wherein each of the first word line contacts is connected to a corresponding one of the plurality of first gate layers;
a plurality of second word line contacts extending through the second mold structure, wherein each of the second word line contacts is connected to a corresponding one of the plurality of second gate layers; and
a plurality of first through vias extending through the second mold structure and electrically connected to the plurality of first word line contacts.
